(19) United States
(12) Patent Application Publication
(10) Pub. No.: US 2009/0297880 A1
(43) Pub. Date: Dec. 3, 2009

(54) Electromagnetically transparent bright resin products and processes for production

(75) Inventors: Yosuke Maruoka, Aichi-ken (JP); Hiroshi Watarai, Aichi-ken (JP); Mamoru Kato, Aichi-ken (JP); Takayasu Ido, Aichi-ken (JP)

Correspondence Address: POSZ LAW GROUP, PLC, 12040 SOUTH LAKES DRIVE, SUITE 101, RESTON, VA, 20191, US

(73) Assignee: TOYODA GOSEI CO., LTD., Aichi-ken (JP)

(21) Appl. No.: 12/453,746

(22) Filed: May 21, 2009

(30) Foreign Application Priority Data
May 30, 2008 (JP) 2008-143894

(51) Int. Cl. B32B 15/08; C23C 14/34; B05D 3/02; B32B 3/10

(52) U.S. Cl. 428/651; 204/192.15; 427/383.1; 428/209

(57) ABSTRACT

The electromagnetically transparent bright resin product includes a resin base 11 made of a polycarbonate (PC), an aluminum (Al) film 13 deposited on the resin base 11 by sputtering, and a chromium film 12 deposited on the aluminum film 13 by sputtering. After the deposition, the films 13 and 12 were heated at 120° C. for 2 hours together with the resin base 11. The aluminum film 13 and the chromium film 12 are hence present as a film of a discontinuous structure.

### BACKGROUND OF THE INVENTION

1. Field of the Invention

The present invention relates to electromagnetically transparent bright resin products including a resin base and a chromium film formed thereover and to processes for producing the electromagnetically transparent bright resin products.

2. Description of the Related Art

At present, surfaces of radiator grills and the like which are made of a resin are often plated to impart brightness (metallic luster) thereto from the standpoint of appearance. A plated product which is inhibited from suffering stress cracking and can hence be prevented from decreasing in appearance quality and which is excellent in corrosion resistance and weather resistance has been proposed. This plated product, as described in patent document 1, includes a chromium film having a thickness regulated to about 400 Å and thereby having crystal grain boundaries. Those effects are because the chromium film haves crystal grain boundaries. Specifically, even when the plated product receives an external stress, this merely increases the distance between adjacent crystal grains and hardly results in stress imposition on the metal itself (chromium). Namely, there is no possibility that the metal film (chromium film) might crack.

On the other hand, there are cases where a motor vehicle is equipped with a radar apparatus for distance measurement that warns the driver that the vehicle has approached a nearby object, for the purpose of improving the safety thereof. The radar apparatus is disposed at various parts of the motor vehicle, e.g., at the back of the radiator grille, back panel, etc. Such a radar apparatus emits an electromagnetic wave toward an object to measure the distance to the object. Because of this, if a substance (e.g., a metal) that intercepts the electromagnetic wave is present between the radar apparatus and the object, the radar apparatus cannot perform its function. Consequently, the automotive exterior resin products located in front of the radar apparatus, such as, e.g., the radiator grille (radar apparatus cover part), have also come to be required to have electromagnetic transparency.

In order to satisfy the requirement, an indium (In) film capable of becoming a film of a discontinuous structure (sea-island structure) has been proposed as a bright deposit having electromagnetic transparency.

However, the cost of indium is rising in these days, and it has hence become necessary to substitute the metal with another metal (in particular, an inexpensive metal).

Patent Document 1: JP-A-9-70920

It has been newly found that when a chromium film is deposited on a resin base and thereafter heated together with the resin, then the chromium film develops cracks which are so fine as to exert no influence on the appearance and thereby comes to have a discontinuous structure, and that the chromium film thus treated has an increased surface resistance and is reduced in electromagnetic-wave attenuation (more highly transmits electromagnetic waves).

### SUMMARY OF THE INVENTION

Accordingly, an object of the invention is to provide an electromagnetically transparent bright resin product that includes a chromium film having a discontinuous structure and, hence, has electromagnetic transparency although bright. Another object of the invention is to provide a process for producing this electromagnetically transparent bright resin product.

### (A) Electromagnetically Transparent Bright Resin Products

The invention provides an electromagnetically transparent bright resin product which includes a resin base and a chromium film formed on the resin base, the chromium film having a discontinuous structure and a thickness of 20 nm or larger.

The invention provides another electromagnetically transparent bright resin product, the product including: a resin base; a metal film formed on the resin base, the metal film having a discontinuous structure and made of a metal having a higher light reflectance than chromium; and a chromium film formed on the metal film, the chromium film having a discontinuous structure and a thickness of 20 nm or larger.

### (B) Processes for Producing Electromagnetically Transparent Bright Resin Products

The invention provides a process for producing an electromagnetically transparent bright resin product that includes depositing a chromium film on a resin base by dry plating and thereafter heating the deposit together with the resin base to thereby convert the chromium film into a film of a discontinuous structure.

The invention further provides another process for producing an electromagnetically transparent bright resin product, the process including depositing a metal film made of a metal having a higher light reflectance than chromium on a resin base by dry plating, depositing a chromium film on the metal film by dry plating, and thereafter heating the deposits together with the resin base to thereby convert the metal film and the chromium film into films of a discontinuous structure.

The mechanism by which a chromium film (including a multilayer film composed of a chromium film and another metal film) cracks is explained here. It is thought that the following two factors are causative of the cracking of a chromium film.

First, chromium is a metal that is high in Pilling-Bedworth proportion (1.99), which is a ratio between the molar volume of a metal oxide and the molar volume of the metal in the metal oxide. Chromium hence shows a considerable volume change (increase) with oxidation. Consequently, the atmospheric oxidation of a chromium film that has been deposited results in the accumulation of many strains (internal stresses) in the film.

Secondly, the coefficient of linear expansion of the resin (the coefficient of linear expansion of polycarbonates: 6.6×10⁻⁵/K) is higher than that of chromium (coefficient of linear expansion: 0.62×10⁻⁵/K) (i.e., the former coefficient is at least 10 times the latter coefficient). Because of this, the resin expands more than the chromium film upon heating and, hence, the chromium film receives external stresses.

As a result, the chromium film cracks due to the internal stresses and the external stresses.

In the case of a multilayer film composed of a chromium film and another metal film, the chromium film thus cracks and this cracking causes the other metal film to crack because this film is in close contact with the chromium film.

Embodiments of the elements in the invention are shown below as examples.

### 1. Resin Base

The shape of the resin base is not particularly limited. Examples thereof include plate materials, sheet materials, and film materials.

The resin constituting the resin base is not particularly limited, except that the resin preferably is optically transparent so as to use the brightness of the metal film(s) (including the chromium film) to be deposited thereon. However, thermoplastic resins are preferred. Examples thereof include polycarbonates (PCs), acrylic resins, polystyrene (PS), poly(vinyl chloride) (PVC), poly(ethylene terephthalate) (PET), acrylonitrile/butadiene/styrene copolymers (ABSs), and polyurethanes. Incidentally, the term “optically transparent” means a conception which includes not only “colorless and transparent” but also “colored and transparent”.

The resin is not particularly limited in the coefficient of linear expansion. However, a resin having a coefficient of linear expansion of 4.0×10⁻⁵ to 15.0×10⁻⁵/K is preferred. More preferred is a resin having a coefficient of linear expansion of 5.0×10⁻⁵ to 10.0×10⁻⁵/K.

### 2. Chromium Film

The chromium to be used for forming the chromium film is not particularly limited, and may be either chromium (pure metal) or a chromium alloy.

The thickness of the chromium metal is not particularly limited. However, it is preferably 20-150 nm, more preferably 25-75 nm.

The conditions of the dry plating for depositing a chromium film having such a thickness are not particularly limited. However, in the case of film deposition by sputtering, for example, the output is preferably 100-800 W and the deposition period is preferably 10-500 seconds. It should, however, be noted that not all of the combinations of an output and a deposition period which are respectively in those ranges are preferred because film thickness is proportional to the product of output and deposition period.

### 3. Metal Film

When the resin product includes a metal film made of a metal having a higher light reflectance than chromium, this resin product has improved brightness (metallic luster).

The metal having a higher light reflectance (reflectance of visible light) than chromium is not particularly limited. This metal may be a pure metal or an alloy. Examples of the metal include aluminum (Al), silver (Ag), nickel (Ni), gold (Au), and platinum (Pt).

The values of light reflectance herein are light reflectance values measured at a wavelength of 550 nm.

The thickness of the metal film is not particularly limited. However, it is preferred that the metal film should be thinner than the chromium film because such a thin metal film is apt to be cracked (apt to be converted to a film of a discontinuous structure) by heating. Although the specific film thickness is not particularly limited, it is preferably 15-150 nm, more preferably 20-75 nm.

For example, in the case where an aluminum film having such a thickness is to be deposited by sputtering, the output is preferably 100-800 W and the deposition period is preferably 10-500 seconds. It should, however, be noted that not all of the combinations of an output and a deposition period which are respectively in those ranges are preferred because film thickness is proportional to the product of output and deposition period.

The term “film of a discontinuous structure” means a film which has many fine cracks (cracks not so large as to exert an influence on appearance) therein and is discontinuous because of the cracks. A metal film of a discontinuous structure has a high surface resistance and is electromagnetically transparent.

### 4. Dry Plating

The dry plating is not particularly limited. However, physical vapor deposition (PVD) is preferred. The physical vapor deposition is not particularly limited, and examples thereof include vacuum deposition, sputtering, and ion plating.

The dry plating to be used for depositing the chromium film and that to be used for depositing the metal film may be the same (same kind of technique) or different (different kinds of techniques).

### 5. Heating

The temperature at which the deposits are heated together with the resin base is not particularly limited. However, the temperature is preferably from 60° C. to the glass transition point (Tg) of the resin base.

The period of the heating is not particularly limited. However, the heating period is preferably from 30 minutes to 8 hours.

### 6. Electromagnetically Transparent Bright Resin Products

Applications of the electromagnetically transparent bright resin products are not particularly limited. Examples thereof include applications that are required to combine brightness and electromagnetic transparency, such as covers for millimeter-wave radar attachment and the housings of communication appliances.

The invention can provide: electromagnetically transparent bright resin products which include a chromium film having a discontinuous structure and, hence, have electromagnetic transparency although bright; and processes for producing these electromagnetically transparent bright resin products.

### BRIEF DESCRIPTION OF THE DRAWINGS

FIG. 1 is a diagrammatic sectional view of a minute part near the surface of an electromagnetically transparent bright resin product as one embodiment of the invention.

FIG. 2 is a photomicrograph of part of the surface of the sample of Comparative Example 6.

FIG. 3 is a photomicrograph of part of the surface of the sample of Example 21.

FIG. 4 is a photomicrograph of part of the surface of the sample of Example 12

FIG. 5 is a photomicrograph of part of the surface of sample 8 after heating.

FIG. 6 is a graph showing the relationship between surface resistance and millimeter-wave attenuation.

FIG. 7 is a graph showing the relationship between surface resistance and reflectance.

FIG. 8 is a graph showing the dependence of surface resistance on the relationship between chromium film thickness and aluminum film thickness.

### DESCRIPTION OF THE PREFERRED EMBODIMENTS

An electromagnetically transparent bright resin product which includes: a platy polycarbonate; an aluminum film which has been formed on the polycarbonate and which is made of aluminum and has a discontinuous structure; and a chromium film formed on the aluminum film and having a discontinuous structure and a thickness of 20 nm or larger.

### Examples

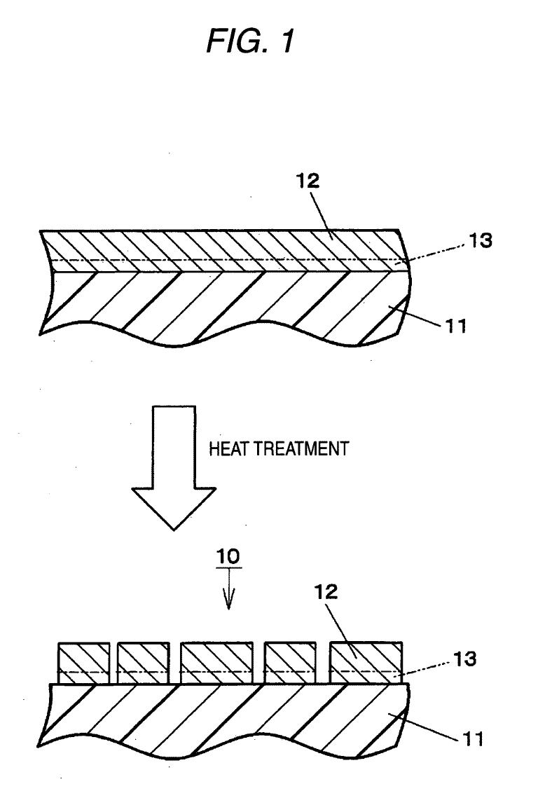

As shown in FIG. 1, an electromagnetically transparent bright resin product 10 of the invention includes a polycarbonate base 11, an aluminum (Al) film 13 deposited on the polycarbonate base 11 by dry plating, and a chromium film 12 deposited on the aluminum film 13 by dry plating. After the deposition of the films 13 and 12, these films were heated together with the polycarbonate base 11. As a result, the aluminum film 13 and the chromium film 12 are present as a film of a discontinuous structure.

The invention will be explained below in more detail by reference to Examples and Comparative Examples.

First, a preliminary test was conducted in which samples obtained by depositing at least one of a chromium film and an aluminum film on a resin base by dry plating were heated at 120° C. for 2 hours and how the surface resistance, transmittance, and reflectance were changed by the heating was examined.

Samples were produced by depositing an aluminum (Al) film on a platy polycarbonate (PC) having a thickness of 3 mm and depositing a chromium (Cr) film thereon, and these samples were examined for surface resistance, transmittance, and reflectance before heating and after the heating. The aluminum film and the chromium film each were deposited by sputtering. As shown in Table 1, deposition conditions (deposition period) were changed to thereby change the thickness of each film (for aluminum, five levels at an output of 200 W, i.e., 60 seconds (film thickness, 23 nm), 90 seconds (film thickness, 35 nm), 120 seconds (film thickness, 45 nm), 180 seconds (film thickness, 70 nm), and nil (film thickness, 0 nm); and for chromium, three levels at an output of 400 W, i.e., 30 seconds (film thickness, 30 nm), 120 seconds (film thickness, 120 nm), and nil (film thickness, 0 nm)). Thus, fourteen kinds of samples were obtained. The measured values of surface resistance, transmittance, and reflectance for each sample are shown in Tables 2 to 4, respectively. In Tables 2 to 4, the upper section and lower section in each cell are a value measure before the heating and one measured after the heating, respectively. The values of surface resistance are given in terms of exponent. For example, in 1.90E+01, E represents 10 and +01 represents the power of 10. The value of 1.90E+01 is therefore 1.90×10¹, i.e., 19.0.

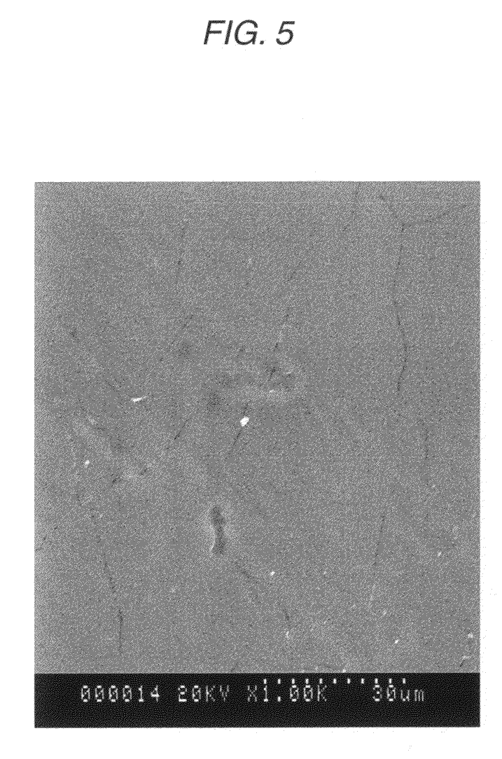

A photomicrograph of the surface (chromium film side) of sample 8 (Al film thickness, 45 nm; Cr film thickness, 30 nm) after the heating is shown in FIG. 5.

TABLE 1
Sample No.

2nd Sputtering
Cr (400 W)

| | | | |
|---|---|---|---|
| | | 30 sec | 120 sec |
| 1st Sputtering | Nil (0 sec) | (30 nm) | (120 nm) |

| | | | | | |
|---|---|---|---|---|---|
| Al | 60 | sec | sample 1 | sample 2 | sample 3 |
| (200 W) | (23 | nm) | | | |
| | 90 | sec | sample 4 | sample 5 | sample 6 |
| | (35 | nm) | | | |
| | 120 | sec | sample 7 | sample 8 | sample 9 |
| | (45 | nm) | | | |
| | 180 | sec | sample 10 | sample 11 | sample 12 |
| | (70 | nm) | | | |

| | | |
|---|---|---|
| Nil | sample 13 | sample 14 |

| | |
|---|---|
| (0 | nm) |

TABLE 2
Surface resistance (unit: Ω/□)

| | | | 2nd Sputtering | | |
|---|---|---|---|---|---|
| | | | Cr (400 W) | | |
| | | | | 30 sec | 120 sec |
| 1st Sputtering | | | Nil (0 sec) | (30 nm) | (120 nm) |
| Al | 60 | sec | 1.90E+01 | 1.28E+01 | 1.04E+02 |
| (200 | (23 | nm) | 1.70E+01 | 1.50E+05 | 1.52E+07 |
| W) | 90 | sec | 7.16E+00 | 6.27E+00 | 3.31E+01 |
| | (35 | nm) | 6.89E+00 | 1.02E+01 | 1.64E+06 |
| | 120 | sec | 4.48E+00 | 4.13E+00 | 6.25E+00 |
| | (45 | nm) | 4.27E+00 | 4.18E+00 | 1.52E+05 |
| | 180 | sec | 2.31E+00 | 2.41E+00 | 2.29E+00 |
| | (70 | nm) | 2.13E+00 | 2.43E+00 | 1.00E+04 |
| | Nil | | | 4.65E+02 | 2.63E+03 |
| | (0 | nm) | | 8.46E+08 | 5.71E+10 |

TABLE 3
Transmittance (unit: % T)

| | | | 2nd Sputtering | | |
|---|---|---|---|---|---|
| | | | Cr (400 W) | | |
| | | | Nil | 30 sec | 120 sec |
| 1st Sputtering | | | (0 sec) | (30 nm) | (120 nm) |
| Al | 60 | sec | 16.17 | 1.82 | 0.07 |
| (200 W) | (23 | nm) | 16.81 | 2.31 | 0.15 |
| | 90 | sec | 3.88 | 0.54 | 0.00 |
| | (35 | nm) | 4.05 | 0.76 | 0.16 |
| | 120 | sec | 1.09 | 0.15 | 0.00 |
| | (45 | nm) | 1.14 | 0.20 | 0.12 |
| | 180 | sec | 0.06 | 0.00 | 0.00 |
| | (70 | nm) | 0.07 | 0.00 | 0.07 |
| | Nil | | | 6.71 | 0.06 |
| | (0 | nm) | | 7.78 | 0.12 |

TABLE 4
Reflectance (unit: R %)

| | | | 2nd Sputtering | | |
|---|---|---|---|---|---|
| | | | Cr (400 W) | | |
| | | | | 30 sec | 120 sec |
| 1st Sputtering | | | Nil (0 sec) | (30 nm) | (120 nm) |
| Al | 60 | sec | 34.35 | 56.31 | 55.44 |
| (200 W) | (23 | nm) | 38.61 | 56.18 | 55.05 |
| | 90 | sec | 58.47 | 62.50 | 61.22 |
| | (35 | nm) | 61.15 | 63.01 | 60.10 |
| | 120 | sec | 61.05 | 64.11 | 65.78 |
| | (45 | nm) | 64.15 | 66.14 | 64.06 |
| | 180 | sec | 65.08 | 61.54 | 61.22 |
| | (70 | nm) | 69.10 | 66.97 | 62.01 |
| | Nil | | | 40.23 | 40.74 |
| | (0 | nm) | | 39.09 | 38.14 |

The deposition conditions other than deposition period are shown below.

As a deposition apparatus, use was made of trade name “i-miller 11”, manufactured by Shibaura Mechatronics Corp. The set conditions included an ultimate vacuum of 5.00×10⁻³ Pa, argon flow rate of 25 sccm, and base rotation speed of 6 rpm. The chamber temperature and the base temperature each were set at 27° C.

During the deposition of each aluminum film, the pressure, current, and voltage were 0.103 Pa, 0.51 A, and 366 V, respectively.

During the deposition of each chromium film, the pressure, current, and voltage were 0.106 Pa, 0.97 A, and 411 V, respectively.

The surface resistance, transmittance, and reflectance of each sample were measured in the following manners. Also in the Examples and Comparative Examples that will be given later, those properties were measured in the same manners.

### (1) Surface Resistance

In the case where the surface resistance to be measured was 1.0×10⁴ (1.0E+04)Ω/□ or lower, the surface resistance was determined by the four-terminal four-probe method in accordance with JIS-K7194.

In the case where the surface resistance to be measured was 1.0×10⁴ (1.0E+04)Ω/□ or higher, the surface resistance was determined by the double-ring probe method in accordance with JIS-K6911.

### (2) Transmittance

A spectrophotometer (trade name “UV-1650PC” manufactured by Shimadzu Corp.) was used to measure transmittance at a measuring wavelength of 550 nm.

The transmittance of the base alone (including neither the chromium film nor any other film) as a reference was taken as 100%.

### (3) Reflectance

A spectrophotometer (trade name “UV-1650PC” manufactured by Shimadzu Corp.) was used to measure reflectance at a measuring wavelength of 550 nm.

The reflectance of a mirror with vapor-deposited aluminum as a reference was taken as 100%.

The results of this test show the following. The samples having a chromium film increased in surface resistance upon heating. However, the samples having a thick aluminum film and a thin chromium film (sample 5, sample 8, and sample 11) showed a relatively small change in surface resistance upon heating. This is because the coefficient of expansion of aluminum (coefficient of linear expansion: 2.39×10⁻⁵/K) is higher than the coefficient of expansion of chromium (coefficient of linear expansion: 0.62×10⁻⁵/K) and is close to the coefficient of expansion of the PC base (coefficient of linear expansion: 6.6×10⁻⁵/K) (i.e., aluminum is intermediate between chromium and PC) and, hence, the aluminum film serves as a buffer to inhibit the chromium film and aluminum film from being cracked by heating. Consequently, the chromium film and the other film developed few (and linear) cracks as shown in FIG. 5 and did not become a film of a discontinuous structure.

The samples obtained by depositing an aluminum film only (sample 1, sample 4, sample 7, and sample 10) did not increase in surface resistance upon heating.

On the other hand, with respect to transmittance and reflectance, the measured values thereof changed little upon heating. These properties were found to undergo a limited influence of heating.

Subsequently, the samples shown in Table 5 were produced in the following manner. An aluminum (Al) film was deposited by sputtering on a polycarbonate (PC) base having a platy shape with a thickness of 3 mm, and a chromium (Cr) film was deposited thereon by sputtering. Alternatively, a chromium film only was deposited by sputtering. Thereafter, 2-hour heating of the deposit(s) was conducted at 120° C. together with the polycarbonate base. Thus, twenty-nine samples of Examples were produced. Furthermore, five samples of Comparative Examples were produced by depositing an aluminum film alone on the same polycarbonate base by sputtering and then heating the deposit together with the polycarbonate base under the same conditions. The chromium films in the Examples had thicknesses of seven kinds ranging from 30 to 120 nm obtained by changing the output (400 W or 600 W) and period (30 seconds, 60 seconds, 90 seconds, or nil) during the deposition. The aluminum films in part of the Examples and in the Comparative Examples had thicknesses of six kinds ranging from 12 to 35 nm obtained by changing the output (200 W or 400 W) and period (20 seconds, 30 seconds, 60 seconds, 90 seconds, or nil) during the deposition.

The chromium film thicknesses obtained at an output of 400 W were 30 nm, 60 nm, and 120 nm under the conditions of 30 seconds, 60 seconds, and 120 seconds, respectively, and those obtained at an output of 600 W were 45 nm, 90 nm, and 135 nm under the conditions of 30 seconds, 60 seconds, and 90 seconds, respectively.

The aluminum film thicknesses obtained at an output of 200 W were 12 nm, 23 nm, and 35 nm under the conditions of 30 seconds, 60 seconds, and 90 seconds, respectively, and those obtained at an output of 400 W were 16 nm and 23 nm under the conditions of 20 seconds and 30 seconds, respectively.

The samples of the Examples and Comparative Examples were examined for transmittance, reflectance, surface resistance, and millimeter-wave attenuation, and the measured values thereof are shown in Table 6. The surface resistance values measured before the heating and those measured after the heating are shown in Table 7. Furthermore, the transmittances and the reflectances are shown in Table 8, and the millimeter-wave attenuations and the appearances are shown in Table 9.

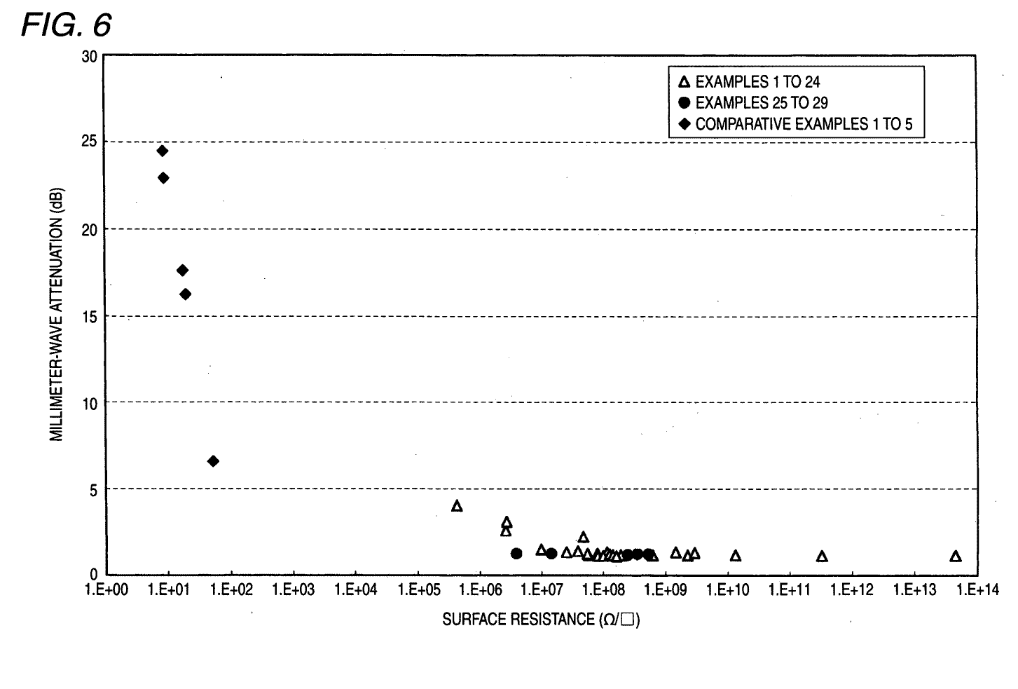

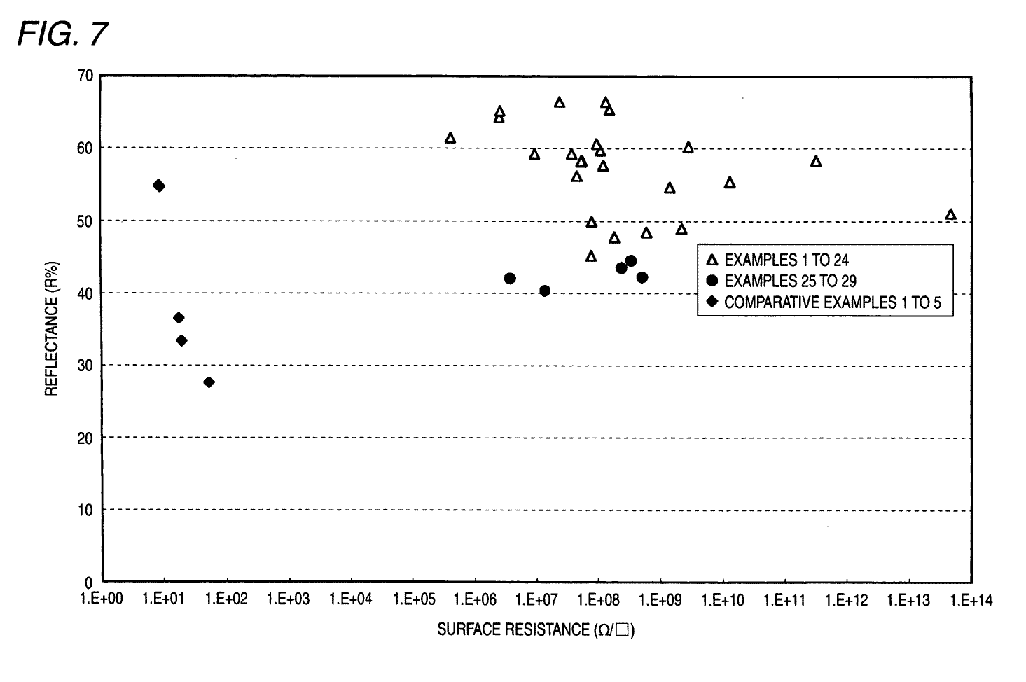

A graph indicating the relationship between surface resistance and millimeter-wave attenuation is shown in FIG. 6, and a graph indicating the relationship between surface resistance and reflectance is shown in FIG. 7.

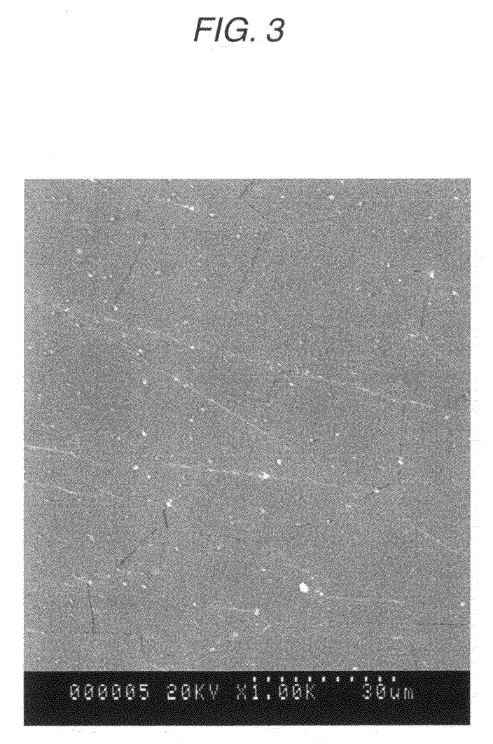

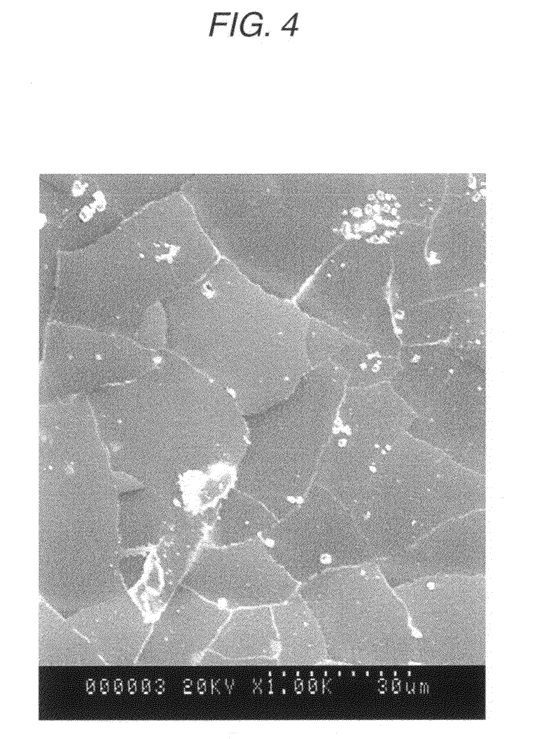

Photomicrographs of the surfaces (chromium film side) of the sample of Example 12 (Al film thickness, 12 nm; Cr film thickness, 120 nm) and sample of Example 21 (Al film thickness, 35 nm; Cr film thickness, 45 nm) are shown in FIG. 3 (Example 21) and FIG. 4 (Example 12).

TABLE 5
T/P No.

| | | | Cr | | | | | | |
|---|---|---|---|---|---|---|---|---|---|
| | | | 400 W | | | 600 W | | | |
| | | | 30 sec | 60 sec | 120 sec | 30 sec | 60 sec | 90 sec | Nil |
| | | | (30 nm) | (60 nm) | (120 nm) | (45 nm) | (90 nm) | (135 nm) | (0 nm) |
| Al | 200 W | 30 sec | Example | Example | Example | Example | Example | Example | Comparative |
| | | (12 nm) | 13 | 22 | 12 | 10 | 11 | 5 | Example 1 |
| | | 60 sec | | | Example | Example | Example | Example | Comparative |
| | | (23 nm) | | | 1 | 20 | 19 | 2 | Example 2 |
| | | 90 sec | | | | Example | Example | Example | Comparative |
| | | (35 nm) | | | | 21 | 18 | 7 | Example 3 |
| | 400 W | 20 sec | Example | Example | Example | Example | Example | Example | Comparative |
| | | (16 nm) | 14 | 23 | 8 | 9 | 24 | 6 | Example 4 |
| | | 30 sec | Example | Example | Example | | Example | Example | Comparative |
| | | (23 nm) | 15 | 16 | 3 | | 17 | 4 | Example 5 |

| | | | | | |
|---|---|---|---|---|---|
| Nil (0 nm) | Example | Example | Example | Example | Example |
| | 25 | 26 | 27 | 28 | 29 |

TABLE 6

| | | | | Millimeter- |
|---|---|---|---|---|
| | | | Surface | wave |
| | Transmittance | Reflectance | resistance | attenuation |
| No. | (% T) | (R %) | (Ω/□) | (dB) |
| Comparative | 45.18 | 27.65 | 5.32E+01 | 6.589 |
| Example 1 | | | | |
| Comparative | 15.36 | 33.42 | 1.97E+01 | 16.270 |
| Example 2 | | | | |
| Comparative | 3.66 | 54.86 | 8.77E+00 | 24.464 |
| Example 3 | | | | |
| Comparative | 28.22 | 36.55 | 1.78E+01 | 17.633 |
| Example 4 | | | | |
| Comparative | 10.13 | 54.65 | 9.07E+00 | 22.894 |
| Example 5 | | | | |
| Example 25 | 1.25 | 43.56 | 2.46E+08 | 1.176 |
| Example 26 | 0.07 | 42.07 | 3.85E+06 | 1.264 |
| Example 27 | 2.91 | 44.54 | 3.53E+08 | 1.233 |
| Example 28 | 0.24 | 42.26 | 5.26E+08 | 1.222 |
| Example 29 | 0.09 | 40.39 | 1.43E+07 | 1.251 |
| Example 13 | 4.60 | 48.44 | 6.16E+08 | 1.154 |
| Example 22 | 0.79 | 45.19 | 8.03E+07 | 1.247 |
| Example 12 | 0.13 | 47.79 | 1.90E+08 | 1.165 |
| Example 10 | 1.67 | 48.96 | 2.26E+09 | 1.159 |
| Example 11 | 0.84 | 49.93 | 8.18E+07 | 1.138 |
| Example 5 | 0.16 | 51.06 | 4.52E+13 | 1.144 |
| Example 1 | 0.15 | 59.25 | 9.66E+06 | 1.492 |
| Example 20 | 0.93 | 59.74 | 1.14E+08 | 1.331 |
| Example 19 | 0.22 | 58.35 | 5.71E+07 | 1.201 |
| Example 2 | 0.16 | 59.24 | 3.89E+07 | 1.400 |
| Example 21 | 0.45 | 61.45 | 4.26E+05 | 4.029 |
| Example 18 | 0.31 | 56.20 | 4.73E+07 | 2.237 |
| Example 7 | 0.22 | 60.60 | 9.91E+07 | 1.122 |
| Example 14 | 3.32 | 54.68 | 1.46E+09 | 1.330 |
| Example 23 | 0.66 | 58.25 | 5.52E+07 | 1.254 |
| Example 8 | 0.33 | 55.42 | 1.33E+10 | 1.178 |
| Example 9 | 1.50 | 60.24 | 2.91E+09 | 1.310 |
| Example 24 | 0.21 | 57.67 | 1.26E+08 | 1.215 |
| Example 6 | 0.23 | 58.37 | 3.24E+11 | 1.143 |
| Example 15 | 1.43 | 64.26 | 2.59E+06 | 2.589 |
| Example 16 | 0.43 | 65.13 | 2.67E+06 | 3.105 |
| Example 3 | 0.13 | 66.38 | 2.53E+07 | 1.349 |
| Example 17 | 0.26 | 66.38 | 1.41E+08 | 1.164 |
| Example 4 | 0.18 | 65.31 | 1.61E+08 | 1.104 |

TABLE 7
Surface resistance (unit: Ω/□)
upper section: before heating
lower section: after heating

| | | | Cr | | | | | | |
|---|---|---|---|---|---|---|---|---|---|
| | | | 400 W | | | 600 W | | | |
| | | | 30 sec | 60 sec | 120 sec | 30 sec | 60 sec | 90 sec | Nil |
| | | | (30 nm) | (60 nm) | (120 nm) | (45 nm) | (90 nm) | (135 nm) | (0 nm) |
| Al | 200 W | 30 sec | 2.70E+01 | 2.32E+02 | 6.89E+01 | 9.73E+01 | 5.90E+02 | 4.15E+03 | 5.32E+01 |
| | | (12 nm) | 6.16E+08 | 8.03E+07 | 1.90E+08 | 2.26E+09 | 8.18E+07 | 4.52E+13 | 5.32E+01 |
| | | 60 sec | | | 7.72E+01 | 8.96E+00 | 4.33E+01 | 1.07E+02 | 1.97E+01 |
| | | (23 nm) | | | 9.66E+06 | 1.14E+08 | 5.71E+07 | 3.89E+07 | 1.97E+01 |
| | | 90 sec | | | | 5.32E+00 | 1.03E+01 | 2.26E+01 | 8.77E+00 |
| | | (35 nm) | | | | 4.26E+05 | 4.73E+07 | 9.91E+07 | 8.77E+00 |
| | 400 W | 20 sec | 2.15E+01 | 2.94E+01 | 7.64E+03 | 1.67E+01 | 3.36E+02 | 7.91E+03 | 1.78E+01 |
| | | (16 nm) | 1.46E+09 | 5.52E+07 | 1.33E+10 | 2.91E+09 | 1.26E+08 | 3.24E+11 | 1.78E+01 |
| | | 30 sec | 7.52E+00 | 1.24E+01 | 3.08E+01 | | 2.01E+01 | 5.15E+01 | 9.07E+00 |
| | | (23 nm) | 2.59E+06 | 2.67E+07 | 2.53E+07 | | 1.41E+08 | 1.61E+08 | 9.07E+00 |

| | | | | | |
|---|---|---|---|---|---|
| Nil (0 nm) | 2.01E+03 | 1.07E+03 | 7.83E+02 | 8.77E+02 | 1.04E+03 |
| | 2.46E+08 | 3.85E+06 | 3.53E+08 | 5.26E+08 | 1.43E+07 |

TABLE 8
Transmittance, Reflectance
upper section: transmittance (unit: % T)
lower section: reflectance (unit: R %)

| | | | Cr | | | | | | |
|---|---|---|---|---|---|---|---|---|---|
| | | | 400 W | | | 600 W | | | |
| | | | 30 sec | 60 sec | 120 sec | 30 sec | 60 sec | 90 sec | Nil |
| | | | (30 nm) | (60 nm) | (120 nm) | (45 nm) | (90 nm) | (135 nm) | (0 nm) |
| Al | 200 W | 30 sec | 4.60 | 0.79 | 0.13 | 1.67 | 0.84 | 0.16 | 45.18 |
| | | (12 nm) | 48.44 | 45.19 | 47.79 | 48.96 | 49.93 | 51.06 | 27.65 |
| | | 60 sec | | | 0.15 | 0.93 | 0.22 | 0.16 | 15.36 |
| | | (23 nm) | | | 59.25 | 59.74 | 58.35 | 59.24 | 33.42 |
| | | 90 sec | | | | 0.45 | 0.31 | 0.22 | 3.66 |
| | | (35 nm) | | | | 61.45 | 56.20 | 60.60 | 54.86 |
| | 400 W | 20 sec | 3.32 | 0.66 | 0.33 | 1.50 | 0.21 | 0.23 | 28.22 |
| | | (16 nm) | 54.68 | 58.25 | 55.42 | 60.24 | 57.67 | 58.37 | 36.55 |
| | | 30 sec | 1.43 | 0.43 | 0.13 | | 0.26 | 0.18 | 10.13 |
| | | (23 nm) | 64.26 | 65.13 | 66.38 | | 66.38 | 65.31 | 54.65 |

| | | | | | |
|---|---|---|---|---|---|
| Nil (0 nm) | 1.25 | 0.07 | 2.91 | 0.24 | 0.09 |
| | 43.56 | 42.07 | 44.54 | 42.26 | 40.39 |

TABLE 9
Millimeter-Wave Attenuation, Appearance
upper section: millimeter-wave attenuation (unit: dB)
lower section: appearance

| | | | Cr | | | | | | |
|---|---|---|---|---|---|---|---|---|---|
| | | | 400 W | | | 600 W | | | |
| | | | 30 sec | 60 sec | 120 sec | 30 sec | 60 sec | 90 sec | Nil |
| | | | (30 nm) | (60 nm) | (120 nm) | (45 nm) | (90 nm) | (135 nm) | (0 nm) |
| Al | 200 W | 30 sec | 1.154 | 1.247 | 1.165 | 1.159 | 1.138 | 1.144 | 6.589 |
| | | (12 nm) | no | no | no | no | no | no | no |
| | | | problem | problem | problem | problem | problem | problem | problem |
| | | 60 sec | | | 1.492 | 1.331 | 1.201 | 1.400 | 16.270 |
| | | (23 nm) | | | no | no | no | no | no |
| | | | | | problem | problem | problem | problem | problem |
| | | 90 sec | | | | 4.029 | 2.237 | 1.122 | 24.464 |
| | | (35 nm) | | | | no | no | no | no |
| | | | | | | problem | problem | problem | problem |
| | 400 W | 20 sec | 1.330 | 1.254 | 1.178 | 1.310 | 1.215 | 1.143 | 17.633 |
| | | (16 nm) | no | no | fine | no | no | fine | no |
| | | | problem | problem | cracks | problem | problem | cracks | problem |
| | | 30 sec | 2.589 | 3.105 | 1.349 | | 1.164 | 1.104 | 22.894 |
| | | (23 nm) | no | no | no | | no | no | no |
| | | | problem | problem | problem | | problem | problem | problem |

| | | | | | |
|---|---|---|---|---|---|
| Nil (0 nm) | 1.176 | 1.264 | 1.233 | 1.222 | 1.251 |
| | no | no | no | no | fine |
| | problem | problem | problem | problem | cracks |

The deposition conditions other than deposition period are shown below.

As a deposition apparatus, use was made of trade name “i-miller 11”, manufactured by Shibaura Mechatronics Corp. The set conditions included an ultimate vacuum of 5.00×10⁻³ Pa, argon flow rate of 25 sccm, and base rotation speed of 6 rpm. The chamber temperature and the base temperature each were set at 27° C.

During the aluminum film deposition at an output of 200 W, the pressure, current, and voltage were 0.103 Pa, 0.51 A, and 366 V, respectively. During the aluminum film deposition at an output of 400 W, the pressure, current, and voltage were 0.106 Pa, 1.03 A, and 401 V, respectively.

During the chromium film deposition at an output of 400 W, the pressure, current, and voltage were 0.106 Pa, 0.97 A, and 411 V, respectively. During the chromium film deposition at an output of 600 W, the pressure, current, and voltage were 0.113 Pa, 1.41 A, and 429 V, respectively.

### (4) Millimeter-Wave Attenuation

Millimeter-wave attenuation was measured with an electromagnetic-wave absorption examination apparatus (free-space method; possessed by Japan Fine Ceramics Center).

Specifically, an electromagnetic wave in the W band (76.575 GHz) emitted from an oscillator was caused to strike on a sample at an incidence angle of 0°, and the electromagnetic wave which had passed through the sample was received with a receiver disposed opposite to the oscillator through the sample. Millimeter-wave attenuation was thus determined.

### (5) Appearance

Each sample was visually examined for appearance. The samples in which no cracks were visually observed were indicated by “no problem”, and the samples in which cracks were visually observed were indicated by “fine cracks”.

The results of those examinations show the following. In the samples of the Examples (twenty-nine samples), the chromium film or the chromium film and aluminum film developed cracks and became a film of a discontinuous structure, as shown in FIGS. 3 and 4. Because of this, these samples had a surface resistance of 1.0×10⁵Ω/□ or higher and a millimeter-wave attenuation of 5 dB or less. Furthermore, these samples had a reflectance of 40 R % or higher.

Those effects in each sample are attributable to the fact that the chromium film had cracked due to the internal stresses caused by partial oxidation in the air and the external stresses imposed by the resin base during the heating. This cracking of the chromium film caused the aluminum film, which was in contact with the chromium film, to crack.

On the other hand, in each of the samples of the Comparative Examples (five samples), the aluminum film had no cracks. These samples had a surface resistance of 6.0×10¹Ω/□ or lower and a millimeter-wave attenuation of 6 dB or more.

This is attributable to the following. Aluminum has a Pilling-Bedworth proportion of 1.28, which is lower than that proportion of chromium, and has a coefficient of linear expansion of 2.39×10⁻⁵/K, which is higher than that coefficient of chromium. Because of this, the stresses (internal stresses and external stresses) that generate in the aluminum film are lower than the stresses generating in chromium films.

Subsequently, the samples shown in Table 10 were produced in the following manner. A polycarbonate having a platy shape with a thickness of 3 mm (PC; glass transition point, 124° C.), an acrylic resin having a platy shape with a thickness of 3 mm (glass transition point, 84° C.), or poly(ethylene terephthalate) having a film shape with a thickness of 200 μm (PET; glass transition temperature, 83° C.) was used as a base to produce nine samples of Examples while changing the temperature during heating (60° C., 80° C., or 120° C.). Three samples of Comparative Examples that employed a glass having a thickness of 1 mm (slide glass) as a base were produced. Furthermore, four samples of Comparative Examples were produced using those four kinds of bases without conducting heating. An aluminum film having a thickness of 23 nm was deposited on each base by sputtering, and a chromium film having a thickness of 135 nm was deposited thereon by sputtering. With respect to the conditions of the sputtering operations, the aluminum film deposition was conducted under the same conditions as for the aluminum film deposition described above conducted at an output of 400 W for a deposition period of 30 seconds. The chromium film deposition was conducted under the same conditions as for the chromium film deposition described above conducted at an output of 600 W for a deposition period of 90 seconds. The period of the heating was 2 hours.

The measured values of surface resistance for those samples of the Examples and Comparative Examples are shown in Table 11, and the measured values of reflectance therefor are shown in Table 12. Incidentally, two specimens were produced in each of the Examples and Comparative Examples, and each of these was examined.

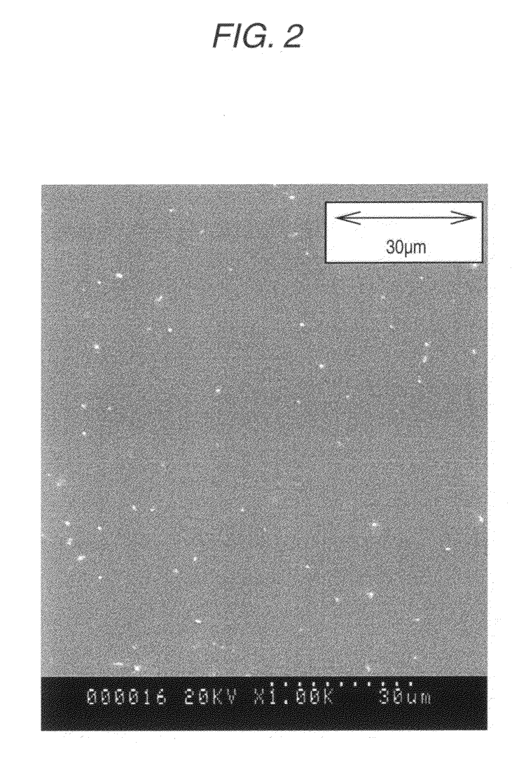

A photomicrograph of the surface (chromium film side) of the sample of Comparative Example 6 (surface resistance, 3.54E+00; reflectance, 66.84 R %) is shown in FIG. 2.

TABLE 10
T/P No.

| | Heating temperature | | | |
|---|---|---|---|---|
| | 120° C. × | 80° C. × | | No heat |
| Base | 2 h | 2 h | 60° C. × 2 h | treatment |
| PC | Example | Example | Example | Comparative |
| (glass transition | 30 | 31 | 32 | Example 9 |
| point: 124° C.) | | | | |
| Acrylic | Example | Example | Example | Comparative |
| (glass transition | 33 | 34 | 35 | Example |
| point: 84° C.) | | | | 10 |
| PET film | Example | Example | Example | Comparative |
| (200 μm) | 36 | 37 | 38 | Example |
| (glass transition | | | | 11 |
| point: 83° C.) | | | | |
| Slide glass | Comparative | Comparative | Comparative | Comparative |
| | Example 6 | Example 7 | Example 8 | Example |
| | | | | 12 |

TABLE 11
Surface resistance (unit: Ω/□)

| | Heating temperature | | | |
|---|---|---|---|---|
| | | | | No heat |
| Base | 120° C. × 2 h | 80° C. × 2 h | 60° C. × 2 h | treatment |
| PC | 1.08E+08 | 1.15E+07 | 1.70E+07 | 6.30E+03 |
| (glass transition | 3.52E+08 | 9.65E+06 | 5.34E+07 | 2.42E+02 |
| point: 124° C.) | | | | |
| Acrylic | unable to | 4.27E+05 | 2.18E+05 | 8.81E+02 |
| (glass transition | be measured | 4.99E+05 | 1.43E+06 | 1.90E+03 |
| point: 84° C.) | because | | | |
| | of deformation | | | |
| PET film | unable to | 6.32E+06 | 5.16E+06 | 7.64E+02 |
| (200 μm) | be measured | 7.83E+06 | 1.23E+06 | 2.18E+02 |
| (glass transition | because | | | |
| point: 83° C.) | of deformation | | | |
| Slide glass | 3.39E+00 | 3.86E+00 | 3.85E+00 | 3.73E+00 |
| | 3.54E+00 | 3.49E+00 | 3.23E+00 | 3.53E+00 |

TABLE 12
Reflectance (unit: R %)

| | Heating temperature | | | |
|---|---|---|---|---|
| | | | | No |
| | | | | Heat |
| Base | 120° C. × 2 h | 80° C. × 2 h | 60° C. × 2 h | treatment |
| PC | 65.14 | 65.48 | 65.23 | 65.89 |
| (glass transition | 65.43 | 65.12 | 65.19 | 66.73 |
| point: 124° C.) | | | | |
| Acrylic | 64.12 | 64.55 | 64.39 | 65.12 |
| (glass transition | 64.87 | 65.23 | 64.83 | 64.83 |
| point: 84° C.) | | | | |
| PET film | 65.34 | 65.23 | 64.73 | 65.83 |
| (200 μm) | 65.28 | 64.91 | 65.23 | 65.12 |
| (glass transition | | | | |
| point: 83° C.) | | | | |
| Slide glass | 66.23 | 66.39 | 67.69 | 66.74 |
| | 66.84 | 67.12 | 66.21 | 67.23 |

The results given above show the following. The samples of the Examples had a surface resistance of 2.00×10⁵Ω/□ or higher, except the samples of Examples 33 and 34, in each of which the surface resistance was unable to be measured because the base had deformed due to the heating conducted at a temperature higher than the glass transition temperature.

On the other hand, in the samples employing a glass as the base, even by the heating as shown in FIG. 2, the chromium film and the other film had not been cracked, and the surface resistance thereof remained low. This is attributable to the fact that the glass had a lower coefficient of expansion (coefficient of linear expansion) than resins and had high hardness.

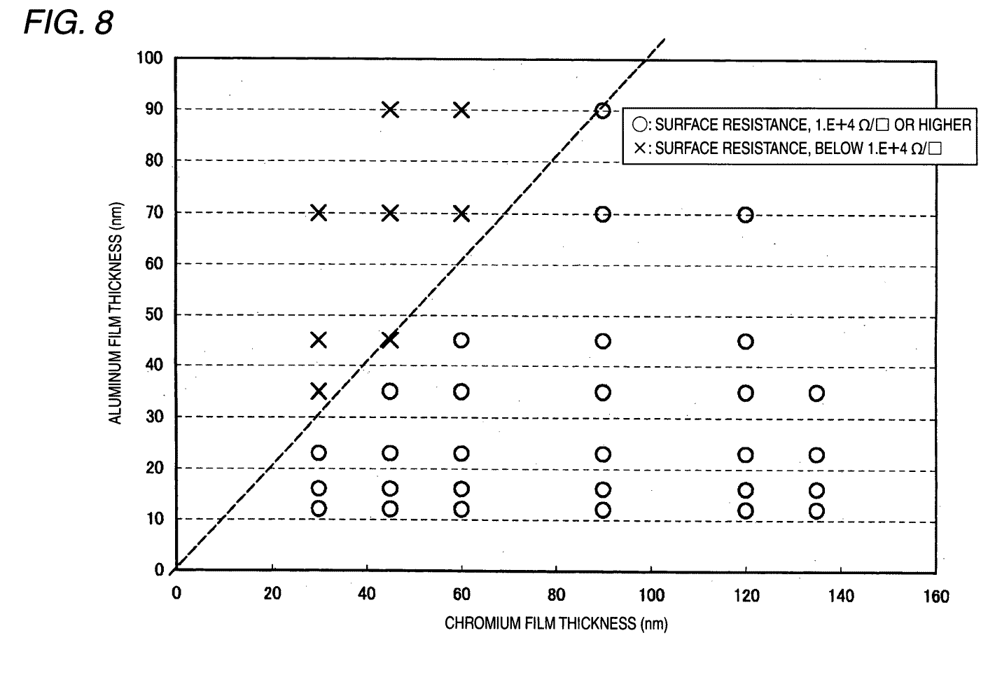

In FIG. 8 is then shown a graph that summarizes differences in surface resistance caused by differences in the thickness of each film in samples each produced by depositing an aluminum film and a chromium film in this order on a resin base and then heating the deposit films at 120° C. for 2 hours together with the resin base.

The following can be seen from FIG. 8. When the thickness of the chromium film is not smaller than the thickness of the aluminum film, then the surface resistance is 1.00×10⁴Ω/□ or higher. This is attributable to the fact that the heating caused the chromium film and aluminum film to crack and each become a film of a discontinuous structure. Furthermore, by regulating the thickness of the aluminum film to 23 nm or larger, the reflectance was elevated to 55 R % or higher.

The invention should not be construed as being limited to the Examples given above. The invention may be practiced in suitably modified modes unless the modifications depart from the spirit of the invention.

What is claimed is:

1. An electromagnetically transparent bright resin product, comprising:
a resin base and a chromium film formed on the resin base, the chromium film having a discontinuous structure and a thickness of 20 nm or larger.

2. The electromagnetically transparent bright resin product, according to claim 1, further comprising:
a metal film formed on the resin base, the metal film having a discontinuous structure and comprising a metal having a higher light reflectance than chromium.

3. The electromagnetically transparent bright resin product according to claim 2, wherein the metal is aluminum.

4. The electromagnetically transparent bright resin product according to claim 2, wherein the metal film is thinner than the chromium film.

5. The electromagnetically transparent bright resin product according to claim 2, wherein the metal film has thickness of 15 to 150 nm.

6. The electromagnetically transparent bright resin product according to claim 1, wherein the resin base is a polycarbonate.

7. The electromagnetically transparent bright resin product according to claim 2, wherein the resin base is a polycarbonate.

8. A process for producing an electromagnetically transparent bright resin product, comprising:
depositing a chromium film on a resin base by dry plating; and
thereafter heating the deposit together with the resin base to thereby convert the chromium film into a film of a discontinuous structure.

9. A process for producing an electromagnetically transparent bright resin product, comprising:
depositing a metal film comprising a metal having a higher light reflectance than chromium on a resin base by dry plating,
depositing a chromium film on the metal film by dry plating, and
thereafter heating the deposits together with the resin base to thereby convert the metal film and the chromium film into films of a discontinuous structure.

10. The electromagnetically transparent bright resin product according to claim 8, wherein the dry plating includes sputtering.

11. The electromagnetically transparent bright resin product according to claim 9, wherein the dry plating includes sputtering.

12. The process for producing an electromagnetically transparent bright resin product according to claim 9, wherein the metal is aluminum.

13. The process for producing an electromagnetically transparent bright resin product according to claim 8, wherein the heating of the deposit(s) together with the resin base is conducted at a temperature in the range of from 60° C. to the glass transition point (Tg) of the resin base.

14. The process for producing an electromagnetically transparent bright resin product according to claim 9, wherein the heating of the deposit(s) together with the resin base is conducted at a temperature in the range of from 60° C. to the glass transition point (Tg) of the resin base.

15. The process for producing an electromagnetically transparent bright resin product according to claim 8, wherein the resin base is a polycarbonate.

16. The process for producing an electromagnetically transparent bright resin product according to claim 9, wherein the resin base is a polycarbonate.

17. The process for producing an electromagnetically transparent bright resin product according to claim 8, wherein the heating of the deposit(s) together with the resin base is conducted in a period from 30 minutes to 8 hours.

18. The process for producing an electromagnetically transparent bright resin product according to claim 9, wherein the heating of the deposit(s) together with the resin base is conducted in a period from 30 minutes to 8 hours.
